(19) United States
(12) Patent Application Publication
(10) Pub. No.: US 2006/0251499 A1
(43) Pub. Date: Nov. 9, 2006

(54) Linear substrate delivery system with intermediate carousel

(76) Inventors: Andrew P. Lunday, San Mateo, CA (US); Michael A. Ackeret, San Jose, CA (US)

Correspondence Address: LAW OFFICES OF CHARLES GUENZER, P O BOX 60729, PALO ALTO, CA, 94306, US

(21) Appl. No.: 11/321,411

(22) Filed: Dec. 29, 2005

Related U.S. Application Data
(60) Provisional application No. 60/679,048, filed on May 9, 2005.

(51) Int. Cl. H01L 21/677

(52) U.S. Cl. 414/217

(57) ABSTRACT

A linear substrate delivery and load lock system including a vacuum transfer chamber having a slit valve connected to a processing chamber and a rotatable carousel having two or more seats for supporting substrates in split path between the substrate source and the processing chamber. Two linear transfer mechanisms transfer the substrates between the source and the carousel and between the carousel and the processing chamber. The transfer mechanism may be disposed mostly located below the carousel and have similar structures but with arms having substrate blades on their end extending in opposite directions to move between the carousel and the source and processing chamber respectively. The carousel moves vertically to effect the transfer to and from the blades. A vertically movable cassette may constitute the substrate source.

### RELATED APPLICATION

This application claims benefit of provisional application 60/679,048, filed May 9, 2005.

### FIELD OF THE INVENTION

The invention relates generally to substrate handing systems. In particular, the invention relates to substrate handling systems involving linear motion from a load lock to a vacuum processing chamber.

### BACKGROUND ART

The fabrication of semiconductor integrated circuits is one of several technologies involving the use of vacuum processing chambers for processing wafers or other substrates in a high vacuum, often using noxious or explosive gases or with plasmas or operating at very high temperatures. Typical chamber pressures for deposition and etching steps range from around a few to many torr for chemical vapor deposition to a millitorr and below for sputtering. Etching pressures typically are intermediate. Establishing very low pressures requires a long pump down from atmospheric pressure and possibly heating of the chamber surfaces to remove adsorbed gases. The pump down problem is exacerbated by the trend toward single-wafer processing reactors in which only a single wafer is processed at a time in the reactor. Some of the processing gases are explosive, such as hydrogen, and should be strictly isolated from ambient oxygen.

Both in a production environment and even in research, it has become common practice to maintain the pressure within the processing reactor chamber at a pressure close to the processing pressure even while a substrate is being transferred into or out of the processing reactor chamber. High-volume semiconductor fabrication lines rely largely on platforms or integrated tools having a central transfer chamber around which are arranged several processing chambers and which is pumped to a reduced pressure. Slit valves are formed on the walls of the transfer chamber and selectively separate the transfer chamber from multiple processing chambers and from a load lock through which wafers are loaded into the system from cassettes originally held at atmospheric pressure. Each of the vacuum-isolated processing chambers, the transfer chamber, and the load lock is independently vacuum pumped. A robot located in the transfer chamber is driven by one or more shafts extending along the central axis of the transfer chamber and is connected to them through magnetic coupling or other types of vacuum feedthroughs. The robot controls a wafer paddle through a frog-leg or other mechanism which can both rotate around the central axis and move into any of the processing chambers or the load lock. Thereby, wafers are passed through the selectively opened slit valves and the transfer chamber as they are transferred between the load lock and the processing chambers. Such a system allows the rapid transfer of wafers between chambers in which processing times for a single step are typically less than a minute.

However, such an integrated tool is not always appropriate. The central transfer chamber is large, and it and the robot are expensive. Many applications, particularly those involving research and development but also those involving low-volume production of high-value circuits, do not require the high throughput or multiple processing chambers available in integrated tools but these application still benefit from a load lock. Production of some components, such as optical circuits and MEMS (micro electromechanical systems), fabricated in silicon-on-insulator (SOI) substrates may require processing times on the order of hours, and such substrates are often processed in relatively small numbers. Photomask reticles used in optical lithographically may in part be produced by semiconductor processing equipment. These reticles typically are square panes of glass having dimensions of approximately 150 mm×110 mm on which metal mask layers are deposited, defined, and cleaned. These high-value items are produced in relatively small quantities. Much larger glass panels are used in the fabrication of flat panel displays. A low-cost load-lock system would be useful in the development phase.

Accordingly, several single-wafer load lock and wafer delivery systems have been proposed. It is understood that such wafer delivery systems can be applied with very little change to rectangular substrates so that the term wafer as used hereafter will include other shapes of substrates. The present inventors have disclosed a magnetically coupled linear substrate delivery system in U.S. Pat. No. 6,935,828, incorporated herein by reference in its entirety. This system relies upon a single wafer paddle (effector) traveling along a single track and magnetically coupled to an external drive to transfer a wafer from an input side of a vacuum pumped transfer chamber into a processing chamber on the opposed processing side of the transfer chamber. In one embodiment, individual wafers are manually placed into the transfer chamber, which is then pumped down to a pressure close to that of the processing chamber. Thereafter, a slit valve between the transfer and processing chambers is opened and the transfer mechanism places the wafer on a pedestal in the processing chamber. The paddle withdraws, the slit valve is closed, and the wafer is subject to the desired processing. After processing, the procedure is reversed. The processed wafer is manually removed from the transfer chamber and a new wafer is inserted. In another embodiment, an entire cassette is placed in or adjacent to the transfer chamber and the chamber is pumped down. The linear transfer mechanism removes one wafer from the cassette with one end of the paddle, withdraws it, and places it upon a raisable pedestal in the transfer chamber. The paddle moves back, and the wafer is then transferred from the pedestal onto the other end of the paddle. The transfer mechanism then moves the paddle and supported wafer into the processing chamber. After processing, the processed wafer is returned to the cassette. The cassette is then vertically moved to position a fresh wafer in alignment to the paddle, and the process is repeated for all wafers in the cassette.

The cassette embodiment offers clear advantages in even low-volume production environments with the infrequent need to pump the transfer chamber between atmospheric and processing pressures. However, the single path between the cassette and processing chamber presents a bottle neck as the processed and unprocessed wafers are transferred between the cassette and the processing chamber along a single path. In some circumstances, the single path severely impacts throughput of the expensive processing chamber because of required cooling time after processing. For example, SOI wafers may need to be annealed at 1300° C. The paddles may be designed to transfer a hot wafer, but the commercially important FOUP cassettes are composed of a plastic material so that it is required to let the wafer cool almost to room temperature before it is placed in the cassette. Only after the cooling period can an unprocessed wafer be moved from the cassette to the processing chamber. During the cooling period, the processing chamber is inactive. Even in processes not requiring cool down, the entire sequence of motions performed by the transfer mechanism, the pedestal elevator, and the pedestal actuator for two different wafer are performed with the processing chamber left empty, thereby reducing processing throughput.

Simplified versions of the production transfer chambers having a central rotating robot have been proposed for use with only a single processing chamber and a cassette load lock arranged around the robot. Although effective, the apparatus are expensive and occupy a large amount of valuable fab floor area.

### SUMMARY OF THE INVENTION

A linearly operating substrate transfer system in which a rotatable carousel can support multiple substrates. Two linear transfer mechanism transfer substrates between the carousel and a processing chamber and another location, such as a substrate cassette.

The transfer mechanism, in one set of embodiments, moves beneath the carousel with its motive sources generally located therebelow. Arms of the transfer mechanisms are projectable from the carousel to the source and process sides respectively.

The two transfer mechanisms may have substantially the same form and be aligned side by side but operate in opposed horizontal directions.

The carousel may be both rotatable and vertically movable to engage the paddles of the transfer mechanisms, which may be held to the same plane.

### BRIEF DESCRIPTION OF THE DRAWINGS

FIG. 1 is a schematic cross-sectional view of a first embodiment of a substrate transfer system of the invention including a vacuum sealable door for inserting a substrate cassette into the transfer chamber.

FIG. 2 is a schematic cross-sectional view of a second embodiment of the invention including a slit valve on the source side of the transfer chamber opening to atmosphere.

FIG. 3 is a schematic cross-section view of a third embodiment of the invention including a slit valve on the source side of the opening to a vacuum sealable chamber for holding either a single substrate or a wafer cassette inserted at atmosphere therein.

FIG. 4 is an orthographic view of an implemented embodiment combinable with the preceding embodiments.

### DETAILED DESCRIPTION OF THE PREFERRED EMBODIMENTS

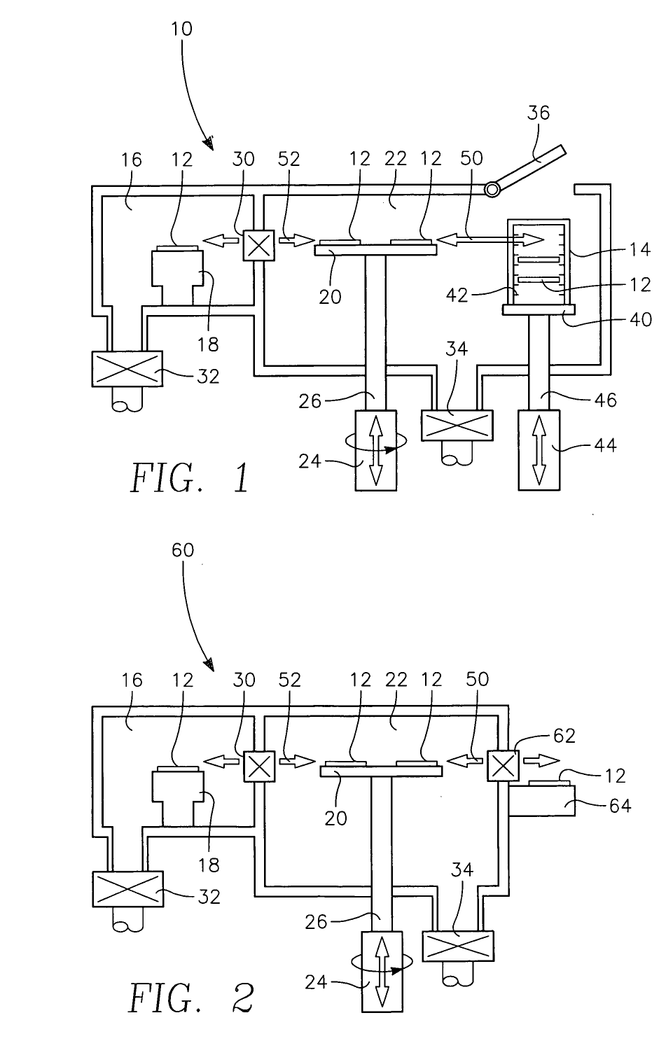

According to one embodiment of the invention, a linear substrate transfer system 10, illustrated functionally in FIG. 1, transfers substrates 12, such as wafers or rectangular reticles, between a substrate source on an input side on the right, such as a cassette 14, and a processing side on the left, such as a single-wafer vacuum processing chamber 16. The processing chamber 16 includes a pedestal 18, which receives the substrate 12 and supports it during processing in harsh environments such as plasmas or high-temperature processing. A rotatable carousel 20 contained within a vacuum-tight transfer chamber 22 is capable of holding at least two substrates 12 at different angular positions of the carousel 20. An actuator 24 supports the carousel 20 on a shaft 26 extending along a central axis of the carousel 20 and can both rotate the carousel 20 and raise and lower it. Thereby, the substrates 12 are moved between the input and output sides. The actuator 24 is preferably positioned below the transfer chamber 22 and the shaft 26 passes through the upper wall of the transfer chamber 22 in a rotatable and axially translatable seal. However, the actuator 24 and its shaft 26 my be positioned above the carousel 20.

The processing reactor 16 is vacuum isolated from the transfer chamber 22 by a selectively openable slit valve 03 through which the substrates 12 and associated transfer arms can pass. A first vacuum pumping system 32 holds the processing chamber 16 at a controlled, typically reduced pressure. Depending upon the type of processing performed in the processing chamber 16, unillustrated gas sources may supply processing or inert gases into the processing chamber 16. A second pumping system 34 controls the pressure within the transfer chamber 22 independently of the first pumping system 32 although the two pumping systems 32, 34 may include a single set of pump and independently controlled valves.

The cassette 14 may be inserted into the transfer chamber 22 through a door 36 sealable to the upper or sidewall of the transfer chamber 22 and then placed on an elevator platform 40 while the transfer chamber 22 is opened to ambient pressure. Thereafter, the door 36 is closed and the second vacuum pumping system 34 reduces the pressure in the transfer chamber 22 to near the pressure within the processing chamber 16. The cassette includes multiple shelves 42 for holding multiple substrates 12, one above the other in parallel horizontal orientations. An elevator actuator 44 selectively raises and lowers an elevator shaft 46 passing through a seal in bottom wall of the transfer chamber 22 and supporting the elevator platform 40 and the supported cassette 14 supported thereon.

A source linear transfer mechanism 50 transfers a substrate 12 between the input side adjacent the cassette 14 and the carousel 20. In one set of embodiments of the invention, to be described in more detail later, the source linear transfer mechanism 50 is typically constrained to operation in a single horizontal plane. The elevator actuator 44 raises and lowers the cassette 14 to present a particular shelf 42 to the source transfer mechanism 50, which inserts its empty blade below the selected shelf 42. The elevator actuator 44 then lowers the cassette 14 to transfer the substrate 12 from the selected shelf 42 to the source transfer mechanism 50. In transferring a processed substrate 12 back to the cassette 14, the loaded blade is positioned above a selected empty shelf 42 and the cassette 14 is raised to transfer the substrate 12 from the blade to the shelf 42.

The process linear transfer mechanism 52, predominantly disposed within the transfer chamber 22, can transfer a substrate 12 between the carousel 12 and the pedestal 18 within the processing chamber 16 through the closable slit valve 30. If the two linear transfer mechanisms 50, 52 are constrained to operated within a plane, vertical movement of the carousel 12 effects the transfer of the substrate 12 between the carousel 20 and the respective transfer mechanism 52. In this case, either the pedestal 18 is vertically movable or vertically movable lift pins are included within it to effect substrate transfer between the pedestal 18 and the transfer mechanism 48. The structure of the schematically linear transfer mechanisms 50, 52 will be described later in more detail.

In operation, the source linear transfer mechanism 50 transfer a fresh substrate 12 from the cassette 14 to the position of a vacant sector or seat of the carousel 20 adjacent the cassette 14. The carousel 20 vertically lifts the fresh substrate 12 off the source transfer mechanism 50 and then rotates, preferably in the raised position, to present the fresh substrate 12 to the process linear transfer mechanism 52, and the carousel 20 lowers the substrate 12 to the process linear trans mechanism 52 which then transfers the fresh substrate 12 through the opened slit valve 30 onto the pedestal 18 within the processing reactor 16. The process linear transfer mechanism 52 retracts from the processing chamber 16, the slit valve 30 is closed, and processing commences. Meanwhile, the elevator actuator 44 raises or lowers the cassette 14 so that the source linear transfer mechanism 50 can transfer a fresh second substrate 12 from the cassette 14 onto the carousel 20 while the first substrate 12 is being processed.

When substrate processing within the processing chamber 16 is completed, the slit valve 30 is opened, and the process linear transfer mechanism 52 transfers the processed first substrate 12 from the processing reactor 16 to the position of a vacant seat on the carousel 20. The carousel 20 lifts the processed first substrate 12 from the process transfer mechanism 52 and is again rotated so that the fresh second substrate 12 is presented to the process transfer mechanism 52 for transfer into the processing chamber 16 and concurrently the processed second substrate 12 is presented to the source transfer mechanism 26. The fresh second substrate is transferred into the processing chamber 16 by operation of the process transfer mechanism 52 and vertical movement of the carousel 20, the slit valve 30 is closed, and processing commences for the second substrate 12 while the source transfer mechanism 50 transfers the first substrate 12 back into the cassette 14. The elevator actuator 44 is again indexed so that the source transfer mechanism 22 can transfer a fresh third substrate 12 from the cassette 14 to the carousel 20, which then lifts the substrate 12 onto the carousel 20. Thereby, two transfer paths are created between the cassette 14 and the processing reactor 16, and a fresh substrate 12 can pass a processed substrate 12 while both are supported on the carousel 20. If the processed substrate 12 requires a substantial cool down period before being reloaded into the cassette 14, the processed substrate 12 may wait on the carousel 20 or on the source transfer mechanism 40 while the next substrate 12 wafer is being processed in the reactor 16.

When all the substrates 12 contained in a cassette 14 have been processed and stored back in the cassette 14, the door 36 of the transfer chamber 26 is opened while the slit valve 30 is closed and the second vacuum pump system 34 is isolated from the transfer chamber 26. The first cassette 14 of processed substrates 12 is replaced on the elevator platform 40 by a second cassette 14 of fresh substrates 12. The door 36 is closed and the second vacuum pump system 34 pumps the transfer chamber 26 down to approximately the processing pressure. The previously described substrate transfer and processing sequence is then repeated.

In a second embodiment of a linear substrate transfer system 60, schematically illustrated in the cross-sectional view of FIG. 2, substrates 12 are transferred one at a time in and out of the transfer chamber 26 through a source slit valve 62. A robot operating at atmospheric pressure or a human operator may place a fresh substrate 12 on a ledge 64 outside of the source slit valve 62. In operation, once a fresh substrate 12 is placed on the pedestal 18 in the process chamber 16 and the process slit valve 30 is closed to allow processing of the substrate, the transfer pump 34 is blocked and the source slit valve 62 is opened so that the transfer chamber 26 is vented to atmosphere. The source transfer mechanism 50 transfers the processed substrate 12 from the carousel 20 through the opened source slit valve 62 onto the ledge 64, where either the operator or external robot replaces it with a fresh substrate 12. The source transfer mechanism 50 transfers the fresh substrate 12 back through the source slit valve 62 onto the carousel 20. The source slit valve 62 is closed, and the transfer vacuum pump 34 pumps the transfer chamber 26 to a reduced pressure. If desired, an inert gas such as nitrogen or argon is back filled into the transfer chamber 26. The source substrate transfer and in particular the long pump down may occur while a substrate continues to be processed in the reactor chamber 16.

Once the processing is completed, the process slit valve 30 is opened but the processing chamber 16 is not exposed to the atmosphere previously held in the transfer chamber 26. As described previously, the source transfer mechanism 50 exchanges the processed substrate 12 with a fresh substrate 12 on the carousel 20. The source slit valve 30 is closed, the carousel 20 rotates, and the source transfer mechanism 50 exchanges the processed substrate 12 on the carousel 20 with a fresh substrate 12 from ledge 64.

In a variant embodiment, which combines the embodiments of FIGS. 1 and 2, the source slit valve 62 is replaced by a door in the transfer chamber wall, possibly the upper wall of FIG. 1, so that the substrate 12 is loaded or unloaded manually or with external equipment directly into or from the opened transfer chamber 26. The substrate 12 may be loaded directly onto the source transfer mechanism 50 or onto an intermediate station.

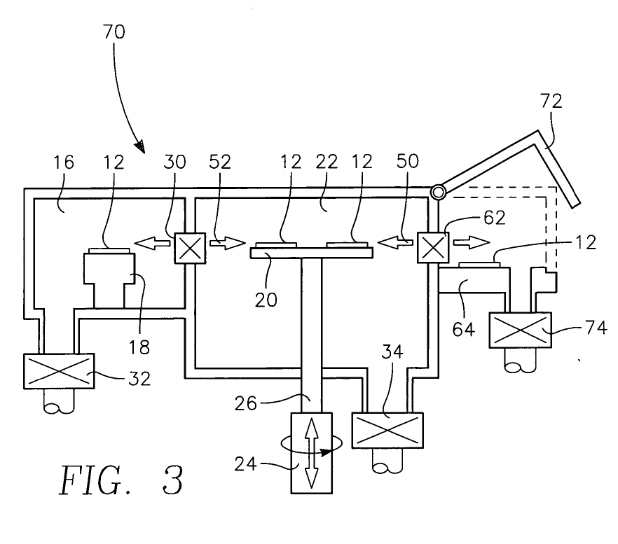

In a third embodiment of a linear substrate transfer system 70, illustrated in FIG. 3, the ledge 64 forms part of a vacuum pumped single-substrate load lock chamber in conjunction with the second slit valve 62 between it and the transfer chamber 26 and a door 72, which when closed seals to the ledge 64 to form the load lock chamber. Substrates 12 are transferred into and out of the system 70 by placing them or removing them from the ledge 64. A third vacuum pump system 74 pumps the load lock chamber to near the pressure of the transfer chamber 26. Thereafter, the second slit valve 62 is opened and the source transfer mechanism 50 transfers substrates 12 between the ledge 64 and the carousel 20. Thereby, the transfer chamber 26 is never exposed to atmosphere. A variant of this embodiment places the cassette 14 and the elevator platform 50 within the just described load lock chamber so that the elevator actuator 44 can present different shelves 42 of the cassette 14 to the source transfer mechanism 50.

The system 70 can be modified to include an cassette elevator 40, 44, 46 of FIG. 1 within the load-lock chamber formed by the door 72 and vacuum pump 74. Once the cassette 14 is loaded into the load-lock chamber, it is pumped down while all its substrates are being processed.

In both embodiments, the transfer chamber 22 remains pumped down for processing of a nearly unlimited number of substrates.

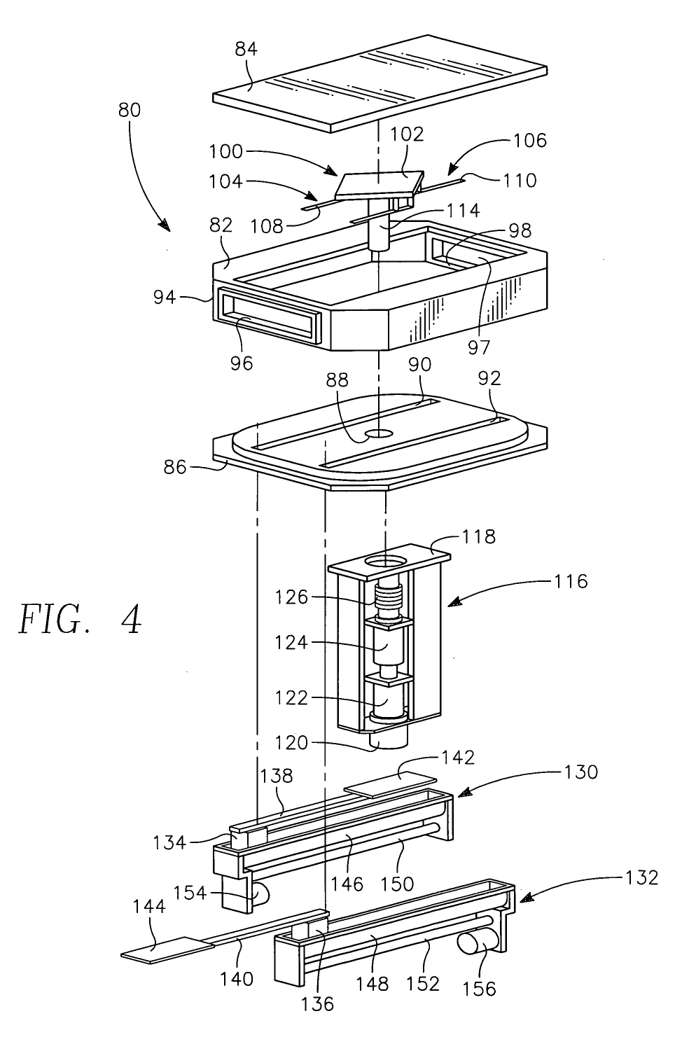

The preceding embodiments are functionally presented. An implemented embodiment of the invention illustrated in the orthographic view of FIG. 4 offers several advantages. A transfer system 80 includes a transfer chamber body 82, which is vacuum sealed on its upper side by a top plate 84 and is sealed to the outside on its lower side by a base plate 86 having a shaft hole 88 and two parallel, laterally offset, and linearly extending slots 90, 92 formed through it between the two slots 90, 92. A process port 96 is formed on one side lateral wall 94 to be sealed to the processing chamber 16 through the process slit valve 30. A corresponding source port 97 penetrates the opposing side wall 98, the form of which depends upon the vacuum isolation to the wafer source. The source port 97 may be a simple passage to a cassette accommodated within an adjacent part of the vacuum chamber, as in FIG. 1, or include a slit valve, as in FIGS. 2 and 3. The two slots 90, 92 may be horizontally offset to accommodate horizontally offset transfer mechanisms, and the process port 96 and the source port 97 are aligned with the two slots 90, 92 respectively.

A two-seat carousel 100 is disposed within the transfer chamber body 82 and includes a horizontally extending carousel plate 102 and two horizontally opposed spiders 104, 106 laterally offset from each other along a horizontal axis, dependent from the carousel plate 102, and designed to support rectangular reticles. Their shape would differ for circular wafers or other substrates. The spiders 104, 106 include respective pairs of dependent arms 108, 110 to support the reticles. The spiders 104, 106 may be modified for circular substrates. A spider shaft 114 supports the carousel plate 102 and is captured and vertically and rotationally moved by an actuator 116 having an actuator plate 118 sealed to the bottom, ambient side of the base plate 86. The actuator 116 includes a pneumatic cylinder 120 and a motor 122. The pneumatic cylinder 120 raises and lowers the spider shaft 114 while the motor 120 rotates it through a rotary section 124 including a ferro-fluidic rotary seal. A bellows 126 provides a vacuum seal for the vertical movement.

A source transfer mechanism 130 and a process transfer mechanism 132 are disposed generally below the base plate 86 of the transfer chamber 82 and vacuum sealed on their upper sides to the lower surface of the base plate 86. The details of the transfer mechanisms 130, 132 are disclosed in previously cited U.S. Pat. No. 6,935,828. They have respective risers 134, 136 rising through the two slots 90, 92 of the bottom plate 86 to support two arms 138, 140 having proximal ends fixed to the risers 134, 136 above the base plate 86. Effectors or blades 142, 144 are fixed to distal ends of the arms 138, 140. The illustrated blades 142, 144 are configured to support rectangular glass reticles. Other configurations are well known for semiconductor wafers and other substrates. The blades 142, 144 are sized to pass between the respective pairs of arms 106, 108 as the carousel 100 is raised and lowered to transfer reticles between the seats of the carousel 100 and the blades 142, 144

Semi-tubular vacuum-tight nacelle covers 146, 148 seal the bottoms of the transfer mechanisms 130, 132. Lead screws 152, 154 are turned by respective motors 154, 156 to linearly drive magnet assemblies, all in atmosphere. The magnet assemblies are magnetically coupled across the nacelle covers 146, 148 to linearly move the blades 142, 144 within the transfer chamber 82 and through its process and source ports 96, 97.

As illustrated, the arm 138 and its blade 142 of the source transfer mechanism 130 point in one direction to allow the blade 142 to move through the source port 97 between the interior of the transfer chamber body 82 and the substrate source, such as a wafer cassette. On the other hand, the arm 140 and blade 144 of the process transfer mechanism 132 point in the other direction to allow the blade 144 to move through the process port 96 between the interior of the transfer chamber body 82 and the process chamber. This configuration differs conventional wafer paddles in that the arm holding the blade is beneath the seat on which the substrate is placed and the paddle is backed onto the seat for substrate transfer. In contrast, conventional carousels use paddles having blades extending from arms towards the carousel.

The size of the transfer chamber 82 may be reduced by making the clearance between the spider arms 108, 110 and the chamber walls only large enough to accommodate the risers 134, 136 of the transfer mechanisms 130, 132 in the extended position illustrated for the process transfer mechanism 132. Then, in those conditions when the spider arms 108, 110 need to be lowered below the level of the spider arms 108, 110 while one of the spider arms 108, 110 contains a substrate that is not desired to be yet transferred, the associated transfer mechanism 130, 132 is projected out of the transfer chamber 82 leaving only the riser within the transfer chamber 82. This situation occurs when a hot processed substrate has been loaded onto the carousel, the processed substrate is rotated to the source side and the fresh substrate is presented to the process side but needs to be lowered onto the process transfer mechanism without the hot substrate being transferred to the source transfer mechanism 130. In this case, the source transfer mechanism 130 is projected out of the transfer chamber 82. This limitation also allows the carousel rotation to be done in the down position if both transfer mechanisms 130, 132 are projected out of the transfer chamber 82 during rotation. As a result, all carousel rotation occurs between processing cycles while the processing chamber is open for the process transfer mechanism 132. An unused shelf position of the cassette 14 may be used for temporary storage of the source transfer mechanism 130.

The transfer system 80 offers several advantages. Two stock transfer mechanisms may be used although different paddles and arms may be used depending on the application. The mechanisms and seals are all located below or at least even with the substrate flow. As a result, any particles generated within the system are unlikely to fall upon the substrates. The footprint of the system is small. This beneficial effect is enabled by the parallel offset transfer mechanism positioned below the carousel and having a throw nearly the size of the transfer chamber.

The illustrated transfer system 80 applies easily to the systems 60 and 70 of FIGS. 2 and 3. Applying it to the system 10 of FIG. 1 in which a cassette is contained within the transfer chamber 82 requires some redesign and a larger chamber. Alternatively, the cassette could be placed within a separate chamber open to the transfer chamber system 80 through the unillustrated and unvalved source port.

The system 80 of FIG. 4 can be adapted to place carousel actuator 24 or the linear transfer mechanisms 130, 132 above the carousel but the lower locations are preferred, especially for the transfer mechanisms.

The carousel 106 of FIG. 4 contains only two seats but the system 80 is simple and compact. The carousel may be designed to have more than two seats but the system will be considerably larger.

It is possible to apply these transfer systems to more complex platforms than the single process chamber and single substrate source of the various described embodiments.

1. A linear substrate transfer system, comprising:
a transfer vacuum chamber;
a rotatable carousel located within the chamber and including at least two seats for accommodating substrates; and
first and second linear transfer mechanisms having respective first and second arms and first and second blades attached to distal ends of the arms and respective first and second support members attached to proximal ends of the arms for moving substrates to and from the seats, wherein, during a transfer of a substrate between the first blade and one of the seats rotated to a first transfer position, the first arm extends below the carousel to an opposite side of the carousel in a first direction towards the first support member.

2. The system of claim 1, wherein the transfer vacuum chamber includes a vacuum sealable first port generally within a plane of the carousel and wherein the first arm extends from the first support member toward the vacuum sealable port and movement of the first linear transfer mechanism causes the first blade to pass through the vacuum sealable port.

3. The system of claim 2, further including a substrate support positioned on a side of the carousel opposite the first port and wherein the second arm extends from the second support member to the second blade in a second direction towards the substrate support and movement of the second linear transfer mechanism causes the second blade to move between the carousel and the substrate support.

4. The system of claim 3, wherein the substrate support comprises:
a multi-level substrate storage cassette; and
a vertically movable elevator supporting the cassette.

5. The system of claim 4, wherein the cassette is located in part of the vacuum transfer chamber.

6. The system of claim 4, wherein the cassette is located externally of the vacuum transfer chamber and is accessed by a vacuum sealable second port.

7. The system of claim 3, further comprising a vacuum sealable second port in the wherein the vacuum transfer chamber positioned between the carousel and the substrate support.

8. The system of claim 2, further comprising:
a vacuum door in a chamber portion in open communication with the transfer vacuum chamber; and
an vertically movable elevator having a cassette support surface for receiving a cassette which contains substrates and is transferrable into the chamber portion through the vacuum door;
wherein the second arm extends from the second support member to the second blade in a second direction towards the elevator and movement of the second linear transfer mechanism causes the second blade to move between the carousel and the cassette.

9. The system of claim 1, wherein the carousel is additionally vertically movable.

10. A linear substrate transfer system, comprising:
a vacuum transfer chamber and including a vacuum sealable process port;
a rotatable and vertically movable carousel located within the transfer chamber and including at least two seats for accommodating substrates thereon;
a substrate source disposed on a side of the carousel opposed to the process port;
two linear transfer mechanisms having mechanical movements located below the carousel and having respective arms extendable in opposite directions through the process port and adjacent to the substrate source respectively to transfer substrates to and from the seats of the carousel.

11. The system of claim 10, wherein the two linear transfer mechanisms are aligned anti-parallel and offset in a direction of movement of the arms.

12. The system of claim 10, wherein the substrate source includes:
a substrate cassette having a plurality of vertically offset shelves for accommodating multiple substrates; and
an elevator supporting and vertically moving the cassette.

13. A method of processing substrates, comprising the steps of:
transferring an unprocessed first substrate onto a first seat of a carousel located at a first angular position;
rotating the carousel so the first seat is located at a second angular position;
transferring the first substrate from the first seat at the second angular position to a processing chamber through an opened valve;
closing the valve and processing the substrate in the processing chamber;
with the first seat located at the second angular position transferring an unprocessed onto a second seat of the carousel located at the first angular position; and
opening the valve and transferring the processed first substrate to the first seat located at the first angular position;
rotating the carousel so that the first seat supporting the processed first wafer is located at the first angular position; and
transferring the processed first substrate from the first seat located at the first angular position.

14. The method of claim 13, wherein the two transferring steps include vertical movement of the carousel.

15. The method of claim 13, wherein the processed first substrate is cooled on the carousel while the second substrate is being processed in the process chamber.
